(19) United States
(12) Patent Application Publication
(10) Pub. No.: US 2026/0033227 A1
(43) Pub. Date: Jan. 29, 2026

(54) METAL MASK FOR SHIELDING, NET STRETCHING ASSEMBLY, MASK, AND DISPLAY PANEL

(71) Applicants: CHENGDU BOE OPTOELECTRONICS TECHNOLOGY CO., LTD., Chengdu, Sichuan (CN); BOE Technology Group Co., Ltd., Beijing (CN)

(72) Inventors: Yu Wang, Beijing (CN); Wei Zhang, Beijing (CN); Jiangtao Deng, Beijing (CN); Jianpeng Wu, Beijing (CN); Yan Huang, Beijing (CN); Xiangdan Dong, Beijing (CN)

(73) Assignees: CHENGDU BOE OPTOELECTRONICS TECHNOLOGY CO., LTD., Chengdu, Sichuan (CN); BOE Technology Group Co., Ltd., Beijing (CN)

(21) Appl. No.: 18/993,184

(22) PCT Filed: May 28, 2024
(86) PCT No.: PCT/CN2024/095824

§ 371 Date: Jan. 10, 2025

(30) Foreign Application Priority Data
May 31, 2023 (CN) 202310637598.4

(51) Int. Cl. H10K 71/16; C23C 14/04; H10K 59/122

(52) U.S. Cl. CPC H10K 71/166; C23C 14/042; H10K 59/122

(57) ABSTRACT

The present disclosure provides a metal mask for shielding, a net stretching assembly, a mask and a display panel, which belongs to the technical field of displaying. The metal mask for shielding includes a base plate. The base plate includes the plurality of open areas spaced apart from each other, and the solid material area except the plurality of open areas. The open areas penetrate through the base plate, and the open areas are configured to define a shape of the display area. The solid material area includes at least one through-etching area, different through-etching areas are close to different sides of the open area, at least one through hole is opened in the at least one through-etching area, and an opening size of the at least one through hole is smaller than an opening size of the open area in a plane parallel to the base plate.

### CROSS-REFERENCES TO RELATED APPLICATIONS

This application claims priority to the Chinese patent application filed on May 31, 2023 before the CNIPA, China National Intellectual Property Administration with the application number of 202310637598.4, and the title of “METAL MASK FOR SHIELDING, NET STRETCHING ASSEMBLY, MASK AND DISPLAY PANEL”, which is incorporated herein by reference in its entirety.

### TECHNICAL FIELD

The present disclosure relates to the technical field of displaying, in particular to a metal mask for shielding, a net stretching assembly, a mask and a display panel.

### BACKGROUND

Currently, in a preparation process of an Organic Light Emitting Diode (OLED) display panel, organic light-emitting materials need to be evaporated using a mask for shielding to form red/green/blue pixels in a luminescent layer of the display panel.

Generally, a high-precision metal mask generally includes a frame, a metal mask for shielding and a plurality of Fine Metal Mask (FMM) strips. The metal mask for shielding is welded to the frame, and the FMM strips are welded to the metal mask for shielding, and a process of welding the FMM strips with the metal mask for shielding is called net stretching.

When the mask is used for masked evaporation, the organic light-emitting material is evaporated on a respective display base plate through a plurality of through holes opened on the FMM strips to form the red/green/blue sub-pixels in the luminescent layer, in which one through hole can correspond to one sub-pixel.

In related art, performance of the mask is usually related to color mixing yield of the evaporated red/green/blue sub-pixels, thus affecting product yield of the display panel.

### SUMMARY

A metal mask for shielding is provided in the present disclosure, which includes a base plate, the base plate includes a plurality of open areas spaced apart from each other and a solid material area except the plurality of open areas;
wherein the plurality of open areas penetrate through the base plate, and the plurality of open areas are configured to define a shape of a display area; and
the solid material area includes at least one through-etching area, and different through-etching areas are close to different sides of an open area, and at least one through hole is opened in the at least one through-etching area, and an opening size of the at least one through hole is smaller than an opening size of the open area in a plane parallel to the base plate.

In one or more embodiments, the at least one through-etching area includes a first through-etching area, the first through-etching area includes a plurality of through holes spaced apart from each other, and the plurality of through holes are arranged in array.

In one or more embodiments, the at least one through-etching area includes a second through-etching area, and a through hole in the second through-etching area extends along an edge of a side of the open area close to the second through-etching area.

In one or more embodiments, in a case where the at least one through-etching area includes a first through-etching area, the first through-etching area is arranged close to a first side of the open area, and the second through-etching area is arranged close to a second side of the open area;
wherein a size of the first side in a length direction is smaller than a size of the second side in the length direction.

In one or more embodiments, an opening shape of the through hole includes at least one of a square, a rectangle, a triangle and a circle.

In one or more embodiments, the solid material area further includes a shielding area, the shielding area is arranged around the at least one through-etching area; and the at least one through-etching area includes a third through-etching area, the third through-etching area further includes a first half-etching zone enclosing the through hole, and a thickness of the first half-etching zone is smaller than a thickness of the shielding area.

In one or more embodiments, further including a protective layer, wherein the protective layer is located at a side of the at least one through-etching area away from the base plate, and an orthographic projection of the protective layer on the base plate covers the at least one through-etching area without overlapping with the open area.

Among them, the target through hole is a through hole with a smallest distance from the side of the open area close to the through hole.

In one or more embodiments, the base plate further includes a first sub-frame extending in a first direction and a second sub-frame extending in a second direction; and the solid material area and the plurality of open areas are located in an area enclosed by the first sub-frame and the second sub-frame;
wherein a number of open areas arranged along the first direction is smaller than a number of open areas arranged along the second direction.

In one or more embodiments, a plurality of grips are arranged at intervals on the first sub-frame and/or the second sub-frame, and the plurality of grips extend towards a side away from the open area.

In one or more embodiments, the grips have chamfers, and axial diameters of the chamfers are greater than 5 mm and less than 10 mm.

In one or more embodiments, the plurality of grips are arranged at intervals on the first sub-frame and the second sub-frame; wherein
a number of grips arranged on the first sub-frame is smaller than a number of grips arranged on the second sub-frame; and/or,
sizes of a part of the grips arranged on the first sub-frame extending along the first direction are larger than sizes of a part of the grips arranged on the second sub-frame extending along the second direction.

In one or more embodiments, sizes of first grips located at both end positions of the first sub-frame in the first direction are larger than sizes of second grips in the first direction, wherein the second grips are grips on the first sub-frame except the first grips.

In one or more embodiments, the metal mask for shielding includes a plurality of second grips and a plurality of first grips arranged at a same end of the first sub-frame;
wherein an interval distance between the first grips at the same end is smaller than an interval distance between the second grips.

In one or more embodiments, the second sub-frame includes a plurality of first frame segments spaced apart from each other, each of the plurality of first frame segments covering orthographic projections of a plurality of endpoints of the open area close to the first frame segment on the first frame segment;
wherein at least one third grip is provided on the first frame segment.

In one or more embodiments, a second frame segment is arranged between two adjacent first frame segments, and at least one fourth grip is further provided on the second frame segment, and a size of the at least one fourth grip in the second direction is larger than a size of the at least one third grip in the second direction; and/or the size of the at least one fourth grip in the first direction is larger than the size of the at least one third grip in the first direction.

In one or more embodiments, the solid material area further includes a shielding area, and the shielding area is arranged around the through-etching area; the through-etching area further includes a second half-etching zone surrounding the open area, and a thickness of a solid material of the second half-etching zone is smaller than a thickness of the shielding area.

The present disclosure provides a net stretching assembly, including a frame and the metal mask for shielding, wherein the metal mask for shielding is connected to the frame.

The present disclosure provides a mask, including the metal mask for shielding, or including the net stretching assembly;
wherein the mask further includes a plurality of mask strips, the plurality of mask strips are respectively connected to the plurality of open areas of the metal mask for shielding, a plurality of openings are opened on each of the plurality of mask strips, and the plurality of openings are configured to define shapes of sub-pixels in the display area.

In one or more embodiments, the metal mask for shielding further includes a protective layer, an orthographic projection of the protective layer on the metal mask for shielding covers the through-etching area at a side of the open area;
wherein the orthographic projection of the mask strip on the metal mask for shielding further covers the protective layer.

The present disclosure further provides a display panel, including:
a substrate including a display area and a non-display area; and
a luminescent layer located on a side of the substrate, including a light-emitting pattern located in the display area and at least one edge pattern area located in the non-display area, different edge pattern areas are located on different sides of the display area, wherein the edge pattern area includes at least one edge pattern, and in a plane parallel to the substrate, a size of the edge pattern is smaller than a size of the display area;
wherein the luminescent layer is obtained by evaporating an organic light-emitting material based on the mask.

The present disclosure firstly provides a metal mask for shielding, which specifically includes a base plate. The base plate includes the plurality of open areas spaced apart from each other, and the solid material area except the plurality of open areas. The open areas penetrate through the base plate, and the open areas are configured to define the shape of the display area. The solid material area includes at least one through-etching area, and different through-etching areas are located at different sides of the open area, and at least one through hole is opened in the at least one through-etching area, and the opening size of the at least one through hole is smaller than the opening size of the open area in the plane parallel to the base plate.

Because different through-etching areas can be provided at different sides of the open area on the metal mask for shielding, and the through holes are etched in the through-etching areas, it is equivalent that the through holes are provided at a periphery of the open area, thus avoiding a large area of solid materials to be provided at the periphery of the open area. Therefore, when the metal mask for shielding is welded to the frame and in the net stretching, a problem that wrinkles occur in the solid material area due to uneven force transmission can be reduced due to presence of the through holes, and thus the FMM strips are relatively smoother, in which case the color mixing yield of the red/green/blue sub-pixels in the luminescent layer can be improved, thus facilitating improvement of the product yield of the display panel.

The above description is only an overview of the technical solution of the present disclosure. In order to have a clearer understanding of the technical means of the present disclosure, it can be implemented according to the content of the specification. In order to make the above and other purposes, features, and advantages of the present disclosure more obvious and understandable, the specific embodiments of the present disclosure are listed below.

### BRIEF DESCRIPTION OF THE DRAWINGS

In order to provide a clearer explanation of the technical solutions in the embodiments of the present disclosure or in the related art, a brief introduction will be given to the accompanying drawings required for the description of the embodiments or related art. It is obvious that the accompanying drawings in the following description are some embodiments of the present disclosure. For those skilled in the art, other drawings can be obtained based on these drawings without creative work. It should be noted that the scale and shape of each figure in the accompanying drawings is only for illustration and does not represent the actual scale. The same or similar reference numbers in the accompanying drawings indicate the same or similar elements or elements with the same or similar functions.

FIG. 1 schematically shows a top plan view of a metal mask for shielding according to an embodiment of the present disclosure;

FIG. 2 schematically shows shapes of several through-etching areas and shapes of through holes located in the through-etching areas according to an embodiment of the present disclosure;

FIG. 3 to FIG. 5 schematically show top plan views of three types of metal masks for shielding with octagonal open areas according to an embodiment of the present disclosure;

FIG. 6 schematically shows an enlarged view of a dashed box area in FIG. 5;

FIG. 7 schematically shows an enlarged view of a dashed box area in FIG. 4;

FIG. 8 schematically shows a top plan view of a fourth metal mask for shielding;

FIG. 9 schematically shows an enlarged schematic view of a grip arranged on a first sub-frame in FIG. 8;

FIG. 10 schematically shows an enlarged schematic view of a grip arranged on a second sub-frame in FIG. 8;

FIG. 11 schematically shows a top plan view between a tape of another open area and the second sub-frame;

FIG. 12 schematically shows a top plan view of a net stretching assembly;

FIG. 13 schematically shows a top plan view of a mask;

FIG. 14 schematically shows a top plan view of a display panel; and

FIG. 15 shows an enlarged schematic view of a dotted line box B in FIG. 14.

### DETAILED DESCRIPTION

In order to clarify the purpose, technical solution, and advantages of the embodiments of the present disclosure, a clear and complete description of the technical solution in the embodiments of the present disclosure will be provided below in conjunction with the accompanying drawings. Obviously, the described embodiments are a part of the embodiments of the present disclosure, not all of the embodiments. Based on the embodiments of the present disclosure, all other embodiments obtained by persons skilled in the art without creative work are within the scope of protection of the present disclosure.

In related art, if wrinkles occurs in a mask during welding and net stretching, poor color mixing of red/green/blue sub-pixels may be caused during evaporation, which results in low product yield of the display panel. In addition, there is a certain sagging amount during the welding and net stretching as well as during the evaporation, and in practice, the sagging amount needs to be controlled, and if the sagging amount is large, poor color mixing of red/green/blue pixels is also caused.

For the mask, which includes a frame and a metal mask for shielding, the metal mask for shielding is generally used to define a display area, that is, an area in the luminescent layer where red/green/blue pixels need to be evaporated. FMM strips are welded to the metal mask for shielding for evaporating the red/green/blue pixels in the display area. The metal mask for shielding as an intermediate member is related to the wrinkles and sagging amount of the mask.

With application of the display panel to various devices, the shape of the display area is more abundant. If there is an irregular polygon shaped display area, it is necessary to design irregularly shaped FMM strips, which also poses a challenge to design of the metal mask for shielding. Because design of the metal mask for shielding needs to be adapted to the FMM strips, the irregularly shaped FMM strips results in increase in probability that wrinkles occur and poor controllability of sagging amount due to design of an irregular FMM strip.

In view of this, the present disclosure proposes a solution to solve above technical problems. A core of this solution is to solve a problem of wrinkles in net stretching, and for this the metal mask for shielding is improved. Specifically, a through-etching area is provided on at least one side of an open area of the metal mask for shielding, and a plurality of through holes are provided in the through-etching area, and thus the problem of wrinkles due to uneven stress caused by a large area of solid materials can be avoided.

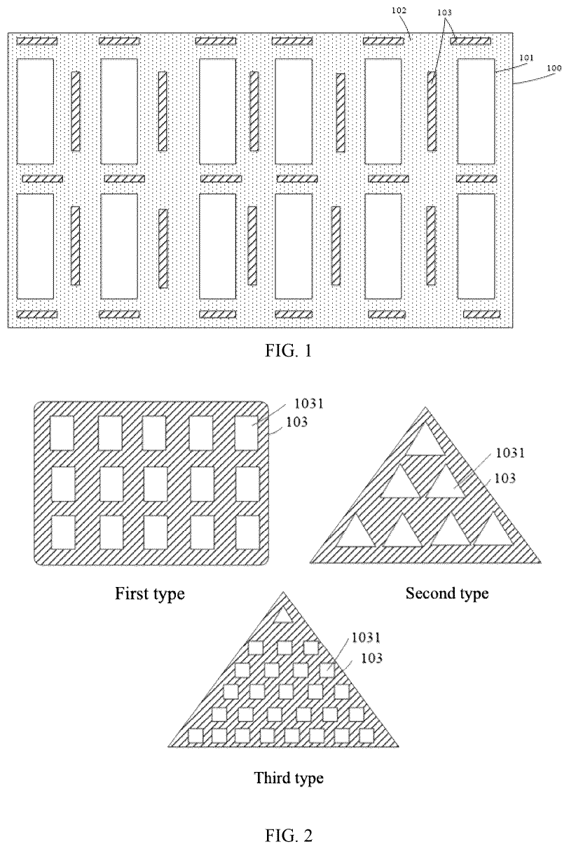

Referring to FIG. 1, there is shown a top plan view of a metal mask for shielding according to an embodiment of the present disclosure, which includes a base plate 100.

The base plate 100 includes a plurality of open areas 101 spaced apart from each other, and a solid material area 102 except for the plurality of open areas 101.

The open areas 101 penetrate the base plate 100, and the open areas 101 are configured to define a shape of the display area 401.

The solid material area 102 includes at least one through-etching area 103, and different through-etching areas 103 are located at different sides of an open area 101, and at least one through hole 1031 is defined in the at least one through-etching area 103, and an opening size of the at least one through hole 1031 is smaller than an opening size of the open area 101 in the plane parallel to the base plate 100.

In this embodiment, the base plate 100 can be made of a metal material. Specifically, the plurality of open areas 101 spaced apart from each other can be opened on the base plate 100, and the open areas 101 need to penetrate through the base plate 100. An area on the base plate 100 except the open areas 101 is the solid material area 102. Generally, the open areas 101 is surrounded by the solid material area 102, and the surrounding solid material area 102 can function in shielding when the organic light-emitting material is evaporated, so as to prevent the organic light-emitting material from being evaporated to other areas except the display area 401.

As described above, the open area 101 is configured to define the display area 401, and the display area 401 can be understood as a light-emitting area in the display panel 400. A shape of the open area 101 can be adapted to a shape of the display area 401. In some embodiments, the open area 101 may be of a regular shape, such as a rectangle, a circle, a square, etc., or of an irregular shape, such as a pentagon, a hexagon, etc. For the irregular shape, the open area 101 is in a plane of the base plate 100, and may include a plurality of sides with different lengths. The open area 101 shown in FIG. 1 is of a long strip shape. In a subsequent embodiment, the open area 101 may be in the irregular shape, which is specifically explained in subsequent embodiments.

The plurality of open areas 101 can be arranged in array. Certainly, in some other examples, the open areas 101 can be arranged irregularly. FIG. 1 shows an array arrangement.

The solid material area 102 may include at least one through-etching area 103. For example, it may include one through-etching area 103, or it may include a plurality of through-etching areas 103. In a case of including the plurality of through-etching areas 103, different through-etching areas 103 may be arranged close to different sides of an open area 101. In one example, a through-etching area 103 may be provided on at least one side of each open area 101, so that the plurality of through-etching areas 103 may be included on the base plate 100.

As shown in FIG. 1, for different open areas 101, the through-etching areas 103 can be arranged at sides facing a same direction. For example, a through-etching area 103 can be respectively arranged at a first side and a second side of each open area 101, and the first side and second side can be two opposite or adjacent sides. In a case where the through-etching area 103 is respectively arranged at two opposite sides of the open area 101, areas of the solid material at both sides of the open area 101 can be symmetrically reduced, so that a force transmitted in a same direction during welding and net stretching can be more uniform, and thus occurrence of wrinkles can be avoided.

As another example, in a case where the first side and the second side are adjacent sides, the through-etching area 103 is respectively arranged at the adjacent sides of the open area 101, which can make forces transmitted in directions of the adjacent sides of the open area 101 more uniform and avoid occurrence of wrinkles at the adjacent sides. FIG. 1 shows cases where the through-etching area 103 is respectively arranged at two adjacent sides and two opposite sides of the open area 101.

Certainly, in another example, a through-etching area 103 can be provided at each side of each open area 101, so that a force transmitted around the open area 101 can be more uniform and a problem of wrinkles around the open area 101 can be reduced. FIG. 1 shows that open areas 101 except an open area 101 located at an edge are provided with through-etching areas 103 at their periphery. For the open area 101 located at the edge, the through-etching areas 103 can be provided only at its three sides.

Specifically, a solid material area 102 with a certain size is reserved between the open area 101 and the through-etching area 103 close to the open area 101, and a size of the reserved solid material area 102 on a plane of the base plate 100 needs to be larger than a size of a wiring area for backplane wiring on the display panel 400, so as to avoid an organic light-emitting material evaporated through the open area 101 from falling on the backplane wiring and reduce product yield.

At least one through hole 1031 penetrating the base plate 100 can be included in each through-etching area 103, and one through-etching area 103 can be provided with one or more through holes 1031. A number of through holes 1031 in different through-etching areas 103 can be the same or different. Shapes of the through holes 1031 in the different through-etching areas 103 can be the same or different. Generally, shapes and numbers of through holes 1031 are not limited and can be specifically set as required.

In an example, as shown in FIG. 1, it shows a way of arranging the through-etching areas 103. Specifically, in a case where a plurality of open areas 101 are arranged in array, the through-etching area 103 can be arranged between every two adjacent open areas 101. For example, in a case where the plurality of open areas 101 are composed of rows of open areas 101 and columns of open areas 101, the through-etching area 103 can be arranged between two adjacent open areas 101 among each row of open areas 101, and similarly, the through-etching area 103 can be arranged between two adjacent open areas 101 among each column of open areas 101. As shown in FIG. 1, FIG. 1 shows a case where the through-etching area 103 is arranged between two adjacent open areas 101 in each row and the through-etching area 103 is arranged between two adjacent open areas 101 in each column of open areas 101.

Certainly, in another example, a number of through holes 1031 in the through-etching area 103 in each row or column can be determined according to a length of a side of the open area 101 close to the through-etching area 103 of this row. The greater a value of the length, the larger the number of through holes 1031 in the through-etching area 103, and the smaller the value of the length, the smaller the number of through holes 1031 in the through-etching area 103.

Specifically, in another example, a shape of the through hole 1031 in the through-etching area 103 between the open areas 101 in a row may be different from a shape of the through hole 1031 in the through-etching area 103 between the open areas 101 in a column. Actually, the shape of the through hole 1031 in the through-etching area 103 in a row direction may be determined according to a size of the open area 101 in the row direction, and a shape of the through hole 1031 in the through-etching area 103 in a column direction may be determined according to a size of the open area 101 in the column direction. For example, as shown in FIG. 1, the larger a length of a side of the open area 101 close to the through-etching area 103, the greater the opening size of the through hole 1031 in the through-etching area 103 close to this side, and the smaller the length of the side of the open area 101 close to the through-etching area 103, the smaller the opening size of the through hole 1031 in the through-etching area 103 close to this side.

The opening size may refer to an aperture of the through hole 1031.

In related art, when the metal mask for shielding is welded to the frame 200 and in net stretching, if there is a large area of solid material at the periphery of the open area 101 of the metal mask for shielding, uneven force transmission may be caused, resulting in wrinkles. With the metal mask for shielding disclosed herein, the through-etching area 103 is located in the solid material area 102 around the open area 101, and at least one through hole 1031 is defined in the through-etching area 103. Due to existence of the through hole 1031, an area of the solid material area 102 around the open area 101 can be reduced, and due to the reduced area of the solid material around the open area 101, the force transmission can be more uniform, thereby reducing occurrence of the wrinkles at the periphery of the open area 101 and occurrence of wrinkles of the FMM strips after the net stretching, making the FMM strips smoother, and further improving color mixing yield of red/green/blue pixels in the luminescent layer and thus facilitating improvement of product yield of the display panel 400.

Further, defining of the through hole 1031 can further reduce a weight of the base plate 100, thereby reducing sagging amount of the base plate 100 in net stretching and evaporation of the organic light-emitting material, further improving the mixed color yield of the red/green/blue pixels in the luminescent layer and thus facilitating improvement of product yield of the display panel 400.

In some examples, an opening shape of the through hole 1031 involves at least one of a square, a rectangle, a triangle and a circle.

In this example, a plurality of through holes 1031 can be laid in one through-etching area 103, and opening shapes of the through holes 1031 can be the same, for example, be all of a square, a rectangle, a triangle or a circle. The opening shapes of the plurality of through holes 1031 in one through-etching area 103 may also be different. For example, the plurality of through holes may include square through holes 1031, rectangular through holes 1031, or triangular through holes 1031.

A shape of the through-etching area 103 may be related to the shapes of the plurality of through holes 1031 included therein.

Referring to FIG. 2, FIG. 2 shows shapes of several through-etching areas 103 and shapes of through holes 1031 located in them. As shown as a first type in FIG. 2, the through-etching area 1013 can be of a rounded rectangle shape, and an opening shape of a through hole 1031 located in the through-etching area can also be of a rectangle shape. In this case, the through hole 1031 can be understood as being of a rectangle shape inscribed in the through-etching area 103. Certainly at least one rectangular through hole 1031 may be included in the through-etching area 103, and these rectangular through holes 1031 may be arranged in array in the through-etching area 103.

As shown as a second type in FIG. 2, the through-etching area 103 can be triangular, and an opening shape of the through hole 1031 included in the through-etching area 103 can be triangular, as shown in FIG. 2, FIG. 2 shows a case where the through-etching area includes a plurality of triangular through holes. Arrangement of the plurality of triangular through holes in the through-etching area 103 can be adapted to a triangular shape of the through-etching area 103, for example, the plurality of through holes 1031 of small triangles are arranged into a large triangle. Certainly, in some examples, the triangular through hole 103 may also involves only one triangular through hole 1031, which is not limited herein.

As shown as a third type in FIG. 2, the through hole 103 is triangular, and the through holes 1031 included in the through hole 103 may include triangular through holes 1031 and square through holes 1031. The square through holes 1031 and the triangular through holes 1031 are arranged in a large triangle.

In a further example, the shape of the through hole 1031 can be preferably triangular or rectangular. The triangular through hole has strong stability, which can improve stability of the base plate 100 under an action of a force, thereby reducing generation of wrinkles.

This triangle can be an equilateral triangle, an isosceles triangle and a right triangle. Specifically, the shape of the through-etching area 103 can be determined according to a shape of the solid material area 102 at a side of the open area 101, and then an appropriate triangular through hole 1031 can be selected.

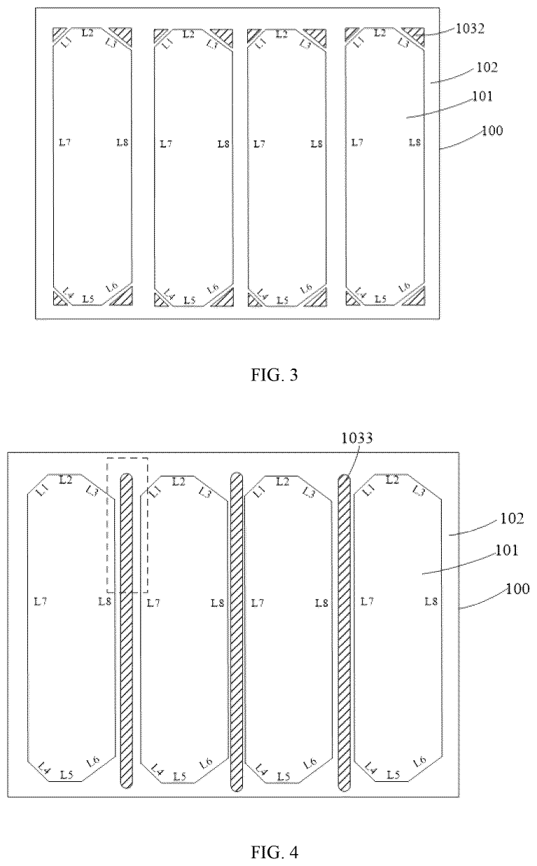

Referring to FIG. 3 to FIG. 5, there are shown top plan views of three types of metal masks for shielding with octagonal open areas 101. As shown in FIGS. 3 to 5, the open area 101 may include eight sides such as L1 to L8. Sides L1, L2 and L3, and L4, L5 and L6 are short sides of the open area 101, and sides L7 and L8 are long sides of the open area 101. The sides L1 and L3 can be symmetrical with respect to the side L2, and certainly, they can also be asymmetrical; and the sides L4 and L6 can be symmetrical with respect to the side L5, and certainly, they can also be asymmetrical. The sides L7 and L8 are two opposite sides.

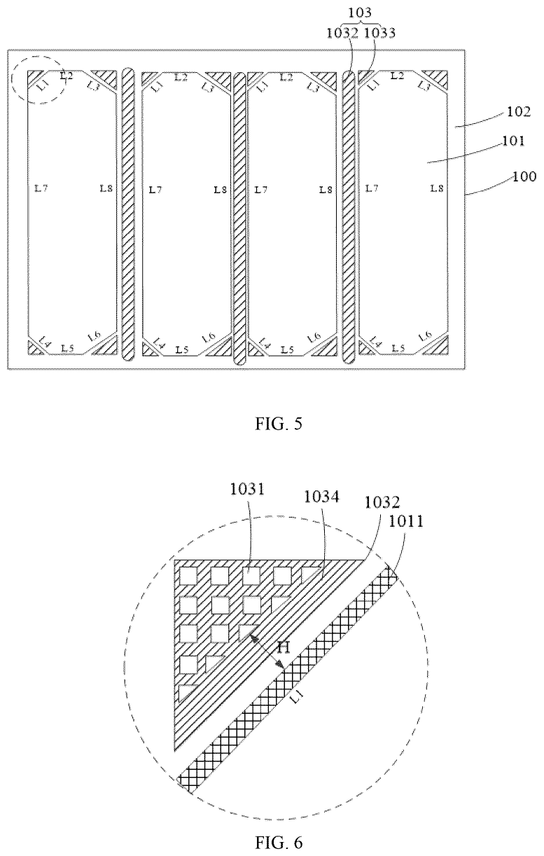

As shown in FIG. 3 to FIG. 5, when the open area 101 is of an irregular polygon shape, the metal mask for shielding may include at least one first through-etching area 1032 and/or at least one second through-etching area 1033. For example, as shown in FIG. 3, a plurality of first through-etching areas 1032 may be included, and different first through-etching areas 1032 are arranged at different sides of the open area 101. As another example, as shown in FIG. 4, a plurality of second through-etching areas 1033 may also be included, and a different second through-etching area 1033 is located at a side of a different open area 101. For example, as shown in FIG. 5, the metal mask for shielding can include a plurality of first through-etching areas 1032 and a plurality of second through-etching areas 1033. For one open area 101, the first through-etching areas 1032 and the second through-etching areas 1033 can be distributed at multiple sides of the open area 101, that is to say, a first through-etching area 1032 and a second through-etching area 1033 can be included in a through-etching area 103 adjacent to the open area 101.

An opening shape of a through hole 1031 in the first through-etching area 1032 may be different from an opening shape of a through hole 1031 in the second through-etching area 1033. Specifically, a number of through holes 1031 in the first through-etching area 1032 may be greater than a number of through holes 1031 in the second through-etching area 1033.

As shown in FIG. 3, in one example, the first through-etching area 1032 includes a plurality of through holes 1031 spaced apart from each other, and the plurality of through holes 1031 are arranged in array.

A first through-etching area 1032 can be distributed at a third side of each open area 101, and the third side of the open area 101 can be a short side in the open area 101 or certainly can be a long side in the open area 101. In a further example, the first through hole 1032 can be arranged at two short sides of the open area 101, and through holes 1031 in this first through hole 1032 can be arranged in array, so that more through holes 1031 can be distributed at the third side of the open area 101.

For example, the first through-etching area 1032 may be located at a side L1, a side L3, and a side L4 and a side L6 of the open area 101.

A spacing between the through holes 1031 in the first through-etching area 1032 can be smaller, for example, it can be less than 1 mm, and in this way, a plurality of through holes 1031 densely arranged can be formed in the first through-etching area 1032, thus forming a Dummy area in the solid material area 102 at the periphery of the open area 101, which facilitates force transmission in stretching and reducing wrinkles.

As shown in FIG. 4, in one example, the through hole 1031 in the second through-etching area 1033 extends along an edge of a side of the open area 101 close to the second through-etching area.

In this example, the second through-etching area 1033 and the first through-etching area 1032 may be located at different sides of the open area 101. Specifically, the first through-etching area 1032 may be located at a short side of the open area 101, and the second through-etching area 1033 may be located at a long side of the open area 101. Alternatively, the first through-etching area 1032 is located at the long side of the open area 101, and the second through-etching area 1033 can be located at the short side of the open area 101. For example, the first through-etching area 1032 can be located at the side L1, the side L3, the side L4 and the side L6 of the open area 101, and the second through-etching area 1033 can be located at the side L7 and the side L8 of the open area 101, and thus, the plurality of through-etching areas 103 can be formed at the periphery of the open area 101.

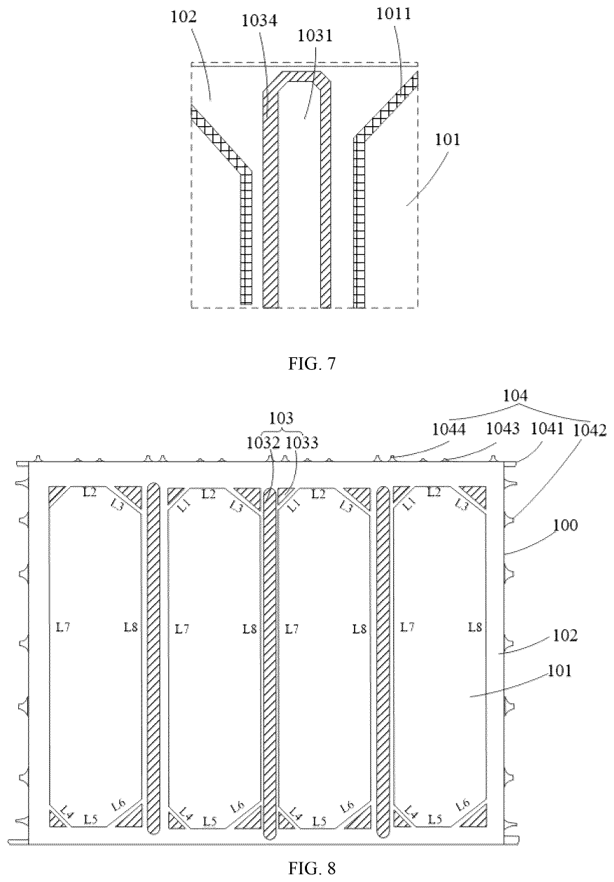

The through hole 1031 in the second through-etching area 1033 extending along an edge of a side of the open area 101 close to the second through-etching area indicates that: the through hole 1031 in the second through-etching area 1033 extends along a length direction of the side of the adjacent open area 101. As shown in FIG. 4, the through hole 1031 in the second through-etching area 1033 can extends along a length direction of the side L7, thus forming a strip-shaped through hole 1031. Certainly, when the second through-etching area 1033 is located at the short side of the open area 101, the through hole 1031 of the second through-etching area 1033 may extend along a length direction of the short side of the open area 101. As shown in FIG. 7, there is shown an enlarged schematic view of the second through-etching area 1033, in which the through hole 1031 extends along the length direction of the side L7.

There may be one through hole or a plurality of through holes 1031 in the second through-etching area 1033, and there can be the plurality of through holes 1031 when the side of the open area 101 close to the second through-etching area is a long side, and the plurality of through holes 1031 can be arranged in sequence along the length direction of the long side of the open area 101.

As a result, strip-shaped through holes 1031 are distributed at a periphery of the long side of the open area 101. With these strip-shaped through holes 1031, the weight can be reduced on one hand, and the force transmission can be more uniform on the other hand, thus reducing occurrence of wrinkles close to the long side of the open area 101.

As shown in FIG. 5, in one example, the through-etching area includes a first through-etching area 1032 and a second through-etching area 1033. The first through-etching area 1032 is located close to the first side of the open area 101 and the second through-etching area 1033 is located close to the second side of the open area.

In this case, a size of the first side in the length direction is smaller than a size of the second side in the length direction, that is, a length of the first side of the open area 101 is smaller than a length of the second side of the open area 101. In this way, the first through-etching area 1032 is located close to the short side of the open area 101, and the second through-etching area 1033 is located close to the long side of the open area 101.

As described above, the first through-etching area 1032 is located close to the short side of the open area 101, and may include a plurality of through holes 1031 arranged in array, and a spacing distance between the through holes 1031 may be small, thereby forming a plurality of dense through holes 1031, and the plurality of dense through holes 1031 form a Dummy area at the short side of the open area 101. The second through-etching area 1033 is located close to the long side of the open area 101, and may include a through hole 1031 extending along the length direction of the long side of the open area 101. As shown in FIG. 5, the first through-etching area 1032 is provided at the side L1, the side L3, the side L4 and the side L6 of the open area 101, and the second through-etching area 1033 is provided at the side L7 and the side L8 of the open area 101, and a strip-shaped through hole 1031 extending along a length direction of a side of the second through-etching area 1033 is provided in the second through-etching area.

Thus, at the periphery of the open area 101, the first through-etching area 1032 can be formed at opposite sides of the open area 101 in a first direction, and the second through-etching area 1033 can be formed at opposite sides of the open area 101 in a second direction, so that the first through-etching areas 1032 and the second through-etching areas 1033 are respectively arranged symmetrically at the periphery of the open area 101.

The first through-etching area 1032 can serve as a Dummy area at the periphery of the open area 101, and the second through-etching area 1033 can serve as a weight-reducing area at the periphery of the open area 101. With cooperation of the first through-etching area 1032 and the second through-etching area 1033, uniformity of force transmission can be improved, and at the same time, the weight of the base plate 100 and the sagging amount can be reduced.

Further, as shown in FIG. 2, the shape of the first through-etching area 1032 can be adapted to the shape of the solid material area 102 at the periphery of the open area 101. As shown as the third types in FIG. 2, the first through-etching area 1032 is triangular in shape. Square through holes 1031 and right-angled triangular through holes 1031 can be included in the first through-etching area 1032. The square through holes 1031 and the right-angled triangular through holes 1031 may be generally arranged in a large triangle. Because the triangle is more stable, structure stability can be maintained in force transmission, and wrinkles can be further avoided.

As shown in FIGS. 3 to 5, the shape of the open area 101 is irregular. For an irregular display area 401, a FMM strip needs to be connected to the open area 101 to form a mask and then the organic light-emitting material can be evaporated with the FMM strip as a mask for the display area 401 of the display panel 400. During evaporation, the organic light-emitting material can be formed on the display panel 400 through openings in the FMM strip, thereby obtaining a sub-pixel 4011.

When the FMM strip is in a regular shape, its orthographic projection on the base plate 100 can cover the open area 101. In this case, both the first through-etching area 1032 and the second through-etching area 1033 may be located in a coverage of the FMM strip, and the FMM strip is provided with a through hole 1031, and thus during evaporation, the organic light-emitting material can easily leak out from the through holes 1031 in the first through-etching area 1032 and the second through-etching area 1033 and be deposited on a non-display area 402 of the display panel 400, thus affecting yield of the display panel 400.

Therefore, in this embodiment, a protective layer can be provided on the metal mask for shielding, and the protective layer can be used to form a barrier between the FMM strip and the through-etching area 103, so as to prevent the organic light-emitting material from being deposited on the non-display area 402 of the display panel 400 and affecting the yield of the display panel 400.

Specifically, an orthographic projection of the protective layer on the base plate 100 covers the through-etching area 103 without overlapping with the open area 101, that is, it only serves a purpose of covering the through-etching area 103.

Further, in a case where the open area 101 included in the metal mask for shielding is an open area 101 with an irregular shape, the through-etching area 103 includes the first through-etching area 1032 and the second through-etching area 1033, and in a case where the second through-etching area 1033 is located between every two adjacent open areas 101, an orthographic projection of the protective layer on the base plate 100 can cover the first through-etching area 1032 without overlapping with the open areas 101, which can be used to prevent the organic light-emitting material from leaking from the through hole 1031 in the first through-etching area 1032 and being evaporated on the non-display area 402 of the display panel 400 when the organic light-emitting material is evaporated by using a mask made of the metal mask for shielding.

In this case, because the first through-etching area 1032 is located close to the short side of the open area 101, when the FMM strip is a regular rectangular strip, the first through-etching area 1032 is located within the coverage of the FMM strip, and thus it is necessary to provide the protective layer here.

The protective layer can be a thin film obtained using a vapor deposition method, which mainly serves to protect the through-etching area 103 without affecting force balance effect by the through-etching area 103 in the solid material area 102.

Certainly, in some other examples, if the shape of the FMM strip is adapted to the shape of the open area 101, for example, the FMM strip is also of an irregular octagonal shape as shown in FIGS. 3 to 5, the through-etching area 103 is outside the coverage of the FMM strip, and the metal mask for shielding may not need to be provided with the protective layer.

In some embodiments, in order to reduce the sagging amount, the weight of the metal mask for shielding can be reduced, specifically, the weight can be reduced by half etching the solid material. Specifically, in one example, the solid material area 102 further includes a shielding area, which is arranged around the through-etching area 103, at least one through-etching area 103 includes a third through-etching area 103, and the third through-etching area 103 further includes a first half-etching zone 1034 enclosing the through hole 1031. A thickness of the first half-etching zone 1034 is smaller than a thickness of the shielding area.

In this embodiment, the solid material area 102 includes not only the through-etching area 103, but also the shielding area surrounding the through-etching area 103, and the shielding area can be located between the through-etching area 103 and the open area 101. Specifically, the shielding area is of solid material. The third through-etching area 103 may be a part of the through-etching areas 103 described above. For example, in a case of including a plurality of first through-etching areas 1032 and a plurality of second through-etching areas 1033, the third through-etching area 103 may be the plurality of first through-etching areas 1032 or the plurality of second through-etching areas 1033. Preferably, because the through hole 1031 of the second through-etching area 1033 extends along the length direction of the side of the open area 101, the third through-etching area 103 may include a first half-etching zone 1034 enclosing the through hole 1031, that is, the solid material around the through hole 1031 is half etching.

A thickness of the first half-etching zone 1034 may be smaller than a thickness of the shielding area. For example, the thickness of the first half-etching zone 1034 may be half or smaller than half of the thickness of the shielding area.

In one example, reference is made to FIGS. 6 and 7, in which FIG. 6 shows an enlarged view of an area with a dashed frame in FIG. 5, and FIG. 7 shows an enlarged view of an area with a dashed frame in FIG. 4. As shown in FIG. 6, in the third through-etching area 103, the first half-etching zone 1034 may be an area in the third through-etching area 103 except the through hole 1031, and enclose the through hole 1031.

In this embodiment, an edge of the through hole 1031 can be half etching for both the first through-etching area 1032 and the second through-etching area 1033 to reduce the thickness and weight of the base plate 100, thereby reducing the sagging amount.

In some embodiments, a width of the first half-etching zone 1034 may be smaller than the aperture of the through hole 1031.

In still other embodiments, the solid material at an opening edge of the open area 101 can be half etching to reduce the sagging amount of the open area 101. Specifically, in this example, the solid material area 102 further includes a shielding area, and the shielding area is arranged around the through-etching area 103, and the through-etching area 103 further includes a second half-etching zone 1011 surrounding the open area 101, and a thickness of the solid material of the second half-etching zone 1011 is smaller than a thickness of the shielding area.

In this embodiment, as shown in FIGS. 6 and 7, the edge of the open area 101 can be half etching to form a second half-etching zone 1011. A thickness of the second half-etching zone 1011 is smaller than the thickness of the shielding area, that is, smaller than a thickness of the base plate 100 itself. For example, the thickness of the second half-etching zone 1011 may be half or smaller than the thickness of the shielding area.

With a generally large opening size of the open area 101, it can be selected to half etching the solid material at an edge of the open area 101, so as to reduce the thickness of the base plate 100, and thus the weight of the base plate 100 can be reduced in a large scale.

In some embodiments, a minimum distance between a target through hole 1031 in the through-etching area 103 and the open area 101 is greater than or equal to 5 mm and less than or equal to 10 mm. The target through hole 1031 is a through hole 1031 with a smallest distance from the side of the open area 101 close to the through hole.

Because the display panel 400 includes a display area 401 and a non-display area 402, in which the luminescent layer is generally located in the display area 401, and a wiring area of signal lines is provided in the non-display area 402. The mask for shielding generally prevent the organic luminescent layer material from being evaporated to the non-display area 402, and the solid material area 102 of the mask for shielding is generally used for shielding.

In this embodiment, because the solid material area 102 includes a plurality of through-etching areas 103, and a plurality of through holes 1031 are opened in the through-etching areas 103, the through holes 1031 need to avoid the wiring area. Specifically, a minimum distance between a target through hole 1031 in the through-etching area 103 closest to the open area 101 and the open area 101 can be greater than or equal to 5 mm.

As shown in FIG. 6, a shortest distance H from the through hole 1031 closest to the open area 101 to the side of the open area 101 is greater than or equal to 5 mm and less than or equal to 10 mm. It should be noted that the distance between the target through hole 1031 and the side of the open area 101 may refer to a vertical distance from the through hole 1031 to an edge of the open area 101, such as a vertical distance from the target through hole 1031 to the side L1 of the open area 101.

Therefore, it can be ensured that the organic luminescent layer material may not be evaporated to a peripheral area of the display area 401 through the through hole 1031 of the through-etching area 103 during evaporation. Because the peripheral area may be bound with backplane wirings of the display panel 400, it can be ensured by provision of the distance above that the organic luminescent layer material cannot be evaporated on the wirings located around the display area 401, so as to avoid affecting a wiring function.

Certainly, a minimum distance from the target through hole 1031 to the open area 101 in this example can be determined according to a size of a backplane wiring area of the display panel 400 to be prepared, that is, in practice, it is not limited to a range from 5 mm to 10 mm.

In some embodiments, for the display area 401 with an irregular shape, arrangement of a plurality of open areas 101 on the metal mask for shielding may also vary to a certain extent. For the metal mask for shielding shown in FIGS. 2 to 4, the open areas 101 are each of an irregular strip shape, which are arranged in array along a side of the metal mask for shielding, that is, arranged in a row. Therefore, it is possible to satisfy evaporation use of an irregularly shaped display area 401.

Specifically, in this embodiment, the base plate 100 further includes a first sub-frame extending in the first direction and a second sub-frame extending in the second direction. The solid material area 102 and a plurality of open areas 101 are located in an area enclosed by the first sub-frame and the second sub-frame. A number of open areas 101 arranged in the first direction is smaller than a number of open areas 101 arranged in the second direction.

The first direction and the second direction may be orthogonal, that is, the first sub-frame and the second sub-frame may be two adjacent sub-frames. The solid material area 102 and the plurality of open areas 101 are located in an area enclosed by the first sub-frame and the second sub-frame. The plurality of open areas 101 can be arranged in array. In arrangement in array, there can be a plurality of open areas 101 along an extension direction in the first direction and a plurality of open areas 101 along an extension direction in the second direction. The number of open areas 101 arranged along the first direction may be smaller than the number of open areas 101 arranged along the second direction.

For example, in arrangement of the open areas 101 on the base plate 100 as shown in FIGS. 3 to 5, in which the first direction is a longitudinal direction when the base plate 100 is viewed from above, and the second direction may be a lateral direction when the base plate 100 is viewed from above, a plurality of open areas 101 are arranged in sequence in the lateral direction to form a row of open areas 101, that is, there are a plurality of open areas 101 in a row direction and only one open area 101 in the longitudinal direction.

With this embodiment adopted, preparation of the irregularly shaped display area 401 can be realized, that is, stretching of the irregularly shaped FMM strip can be realized, so as to adapt to manufacturing needs of an irregularly shaped display screen.

In order to make stress on sides of the metal mask for shielding more uniform during net stretching and welding, a plurality of grips 104 can be provided at intervals on the first sub-frame and/or on the second sub-frame, and the grips 104 extend towards a side away from the open area 101.

In this embodiment, since the number of open areas 101 arranged in the first direction is less than the number of open areas 101 arranged in the second direction, the metal mask for shielding is a rectangular mask with a short side and a long side, and the short side extends along the first direction and the long side extends along the second direction. In order to make the short side and the long side be uniformly stressed in net stretching and welding, a plurality of grips 104 can be arranged on the first sub-frame; or a plurality of grips 104 are arranged on both the first sub-frame and the second sub-frame.

Alternatively, when the short side, that is, a length of the first sub-frame along the first direction is small, that is, the short side is very short, a plurality of grips 104 may be provided only on the second sub-frame.

In the following, several ways of providing the grip 104 are illustrated.

In an arrangement mode, the plurality of grips 104 are arranged on both the first sub-frame and the second sub-frame. Referring to FIG. 8, FIG. 8 shows a top plan view of the fourth metal mask for shielding, and as shown in FIG. 8, sizes of a part of the grips 104 arranged on the first sub-frame in the first direction are larger than sizes of a part of the grips 104 arranged on the second sub-frame in the second direction, and/or a number of the grips 104 arranged on the first sub-frame is smaller than a number of the grips 104 arranged on the second sub-frame.

In an example, the first sub-frame is in a short-side direction of the base plate 100, and sizes of a part of the grips 104 arranged on the first sub-frame along the first direction may refer to widths of the grips 104, which may be larger than the widths of the part of the grips 104 arranged on the second sub-frame. It should be noted that, in this example, the widths of the part of the grips 104 on the first sub-frame are slightly larger than the widths of the part of the partial grips 104 on the second sub-frame.

In another example, the number of grips 104 arranged on the first sub-frame may be smaller than the number of grips 104 arranged on the second sub-frame.

In another example, the number of grips 104 arranged on the first sub-frame may be smaller than the number of grips 104 arranged on the second sub-frame, and the widths of the part of the grips 104 on the first sub-frame may be greater than the widths of the part of the grips 104 on the second sub-frame. In this way, a smaller number of grips 104 with larger sizes are formed on the first sub-frame, while a larger number of grips 104 with smaller sizes are arranged on the second sub-frame. Generally, a grip 104 with a larger size can also bear a larger force and a grip 104 with a smaller size can bear a smaller force. Due to a short length of the first sub-frame, a force borne by arranging the grips 104 with larger sizes can be basically balanced with a force borne by smaller grips 104 arranged on the second sub-frame with a larger length, and in this way, forces borne by the sub-frames of the base plate 100 can be balanced in a case where lengths of the sub-frames are different, thereby avoiding wrinkles during welding and net stretching.

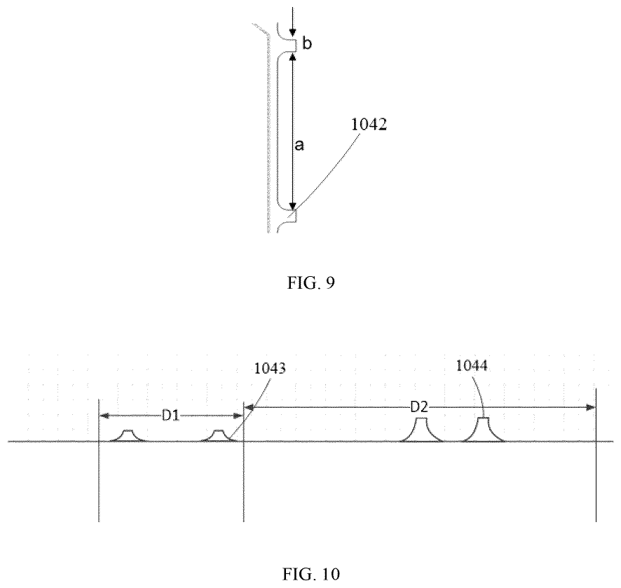

Referring to FIG. 9, FIG. 9 shows an enlarged schematic view of the grips 104 arranged on the first sub-frame in FIG. 8. As shown in FIG. 9, in one example, sizes of first grips 1041 located at both end positions of the first sub-frame in the first direction are larger than sizes of second grips 1042 in the first direction. The second grips 1042 are grips 104 on the first sub-frame except the first grips 1041.

In this example, the plurality of grips 104 arranged on the first sub-frame at least include the first grips 1041 located at both end positions, and the both end positions may refer to a corner position where the first sub-frame is close to the second sub-frame, and at least one first grip 1041 may be arranged at the corner position. It is preferable to arrange two first grips 1041, and there is a spacing distance between two first grips 1041, this spacing distance can be set according to actual needs.

At least one second grip 1042 can be arranged on a frame segment between the both end positions on the first sub-frame, and a width b of the second grip 1042 can be smaller than a width of the first grip 1041. Specifically, a size of the second grip 1042 along the first direction is smaller than a size of the first grip 1041 along the first direction.

In this example, a size of the second grip 1042 located between the both end positions of the first sub-frame in the first direction may be larger than sizes of the part of the grips 104 arranged on the second sub-frame in the second direction. The first grip 1041 can be used to function in positioning in welding, that is, in welding the metal mask for shielding to the frame 200. A large size of the first grip 1041 can improve stress on both ends of the metal mask for shielding, thus improving structural stability between the metal mask for shielding and the frame 200.

The plurality of second grips 1042 provided can ensure stability, and at the same time middle positions of the first sub-frame except the both end positions can be stretched by a force. In addition, the size of the second grip 1042 is smaller than the size of the first grip 1041, so that a stretching force of the second grip 1042 is small, and thus alignment accuracy between the metal mask for shielding and the frame 200 during welding can be fine-tuned, thereby facilitating improvement of alignment accuracy between each FMM strip and the open area 101 in subsequent stretching.

As shown in FIG. 8, in one example, there may be included a plurality of second grips 1042 and a plurality of first grips 1041 at each end of the first sub-frame. A spacing distance a between the second bars 1042 is greater than a spacing distance between the first bars 1041 located at each end.

In this embodiment, a plurality of first grips 1041 can be evenly spaced at each end and a plurality of second grips 1042 can be evenly spaced at a frame segment between the both end positions can be evenly spaced, and the first grips 1041, due to their large stress, are used to ensure the structural stability between the metal mask for shielding and the frame 200, and with evenly spacing of the first grips, a stretching force between endpoints between the metal mask for shielding and the frame 200 can be improved. In a case where the second bars 1042 are equally spaced, it can be ensured that uniform stretching occurs at the middle position of the first sub-frame except the both end positions. In addition, a spacing distance between the second bars 1042 is greater than a spacing distance between the first bars 1041, which can ensure that the structural stability between the metal mask for shielding and the frame 200 may not be affected when the second bars 1042 are used for accuracy fine-tuning, thus ensuring stability and also subsequent alignment accuracy between the FMM strip and the open area 101.

In another arrangement, a plurality of grips 104 are arranged on both the first sub-frame and the second sub-frame. Arrangement positions of the plurality of grips 104 on the second sub-frame can be determined according to a projection position of the open area 101 on a side of the second sub-frame.

Referring to FIG. 10, FIG. 10 shows an enlarged schematic view of a grip 104 arranged on the second sub-frame in FIG. 8. As shown in FIG. 10, the second sub-frame includes first frame segments D1 corresponding to a plurality of open areas 101, and each first frame segment D1 corresponds to one open area 101.

Specifically, the second sub-frame includes a plurality of first frame segments D1 spaced apart from each other, and each of the first frame segments D1 covers orthographic projections of a plurality of endpoints of the open area 101 close to the first frame segment D1 on the first frame segment D1. At least one third grip 1043 is provided on the first frame segment D1.

In this embodiment, as shown in FIG. 10, the second sub-frame has a plurality of spaced-apart first frame segments D1, and positions of the first frame segments D1 correspond to positions of the open areas 101, that is, one open area 101 can correspond to one first frame segment D1, and an orthographic projection of the first frame segment D1 on the open area 101 can cover endpoints of the open area 101 at its side close to the first frame segment D1.

In one example, as shown in FIG. 10, a straight line connecting two endpoints of the open area 101 at its side close to the first frame segment D1 is a side of the open area 101. In this case, the orthographic projection of the first frame segment D1 on the open area 101 can cover a side of the open area 101 close to the first frame segment D1, that is, endpoints of the open area 101 close to the second sub-frame are all located in a projection area of the first frame segment D1 in the open area 101.

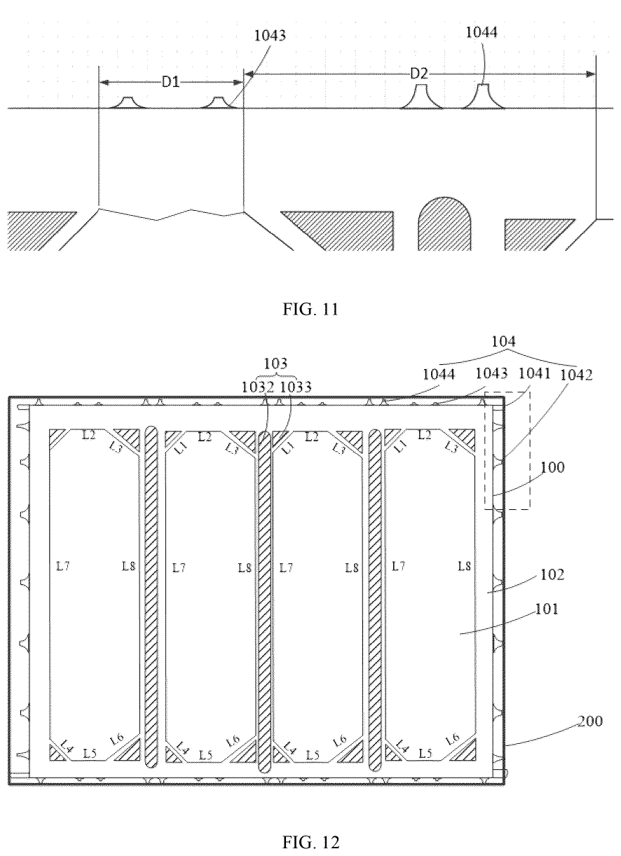

In yet another example, referring to FIG. 11, FIG. 11 shows a top plan view between a shape of another open area 101 and the second sub-frame. In FIG. 11, the straight line connecting two endpoints of the open area at its side close to the first frame segment D1 does not belong to a real side of the open area 101, that is, the open area 101 has a plurality of sides at its part close to the second sub-frame, and the plurality of sides are connected in turn. Therefore, the open area 101 forms a plurality of endpoints at a side of the second sub-frame so as to form a fold-line side. In this case, the plurality of endpoints of the open area 101 at its side close to the second sub-frame can all be in the projection area of the first frame segment D1 in the open area 101.

A third grip 1043 can be arranged on the first frame segment D1, in which case the third grip 1043 can be arranged at a midpoint of the first frame segment D1. Certainly, in some examples, a plurality of third grips 1043 can be evenly spaced on the first frame segment D1. The third grip 1043 is used to provide stretching between the frame 200 and the metal mask for shielding during welding with the frame 200.

Because the third grip 1043 is arranged at a position on the open area 101 corresponding to the second sub-frame, a force for net stretching can be transmitted to the frame 200 through the third grip 1043 of a respective open area 101 in stretching, that is to say, a FMM bar is stretched by a force at a position on the frame 200 corresponding to the open area 101, thus avoiding a problem of large wrinkles on a solid material part around the open area 101 due to weak stretching.

In a further example, as shown in FIG. 10, there is further provided at least one fourth grip 1044 on the second frame segment D2 between two adjacent first frame segments D1, and a size of the fourth grip 1044 in the second direction is larger than a size of the third grip 1043 in the second direction; and/or, a size of the fourth grip 1044 in the first direction is larger than a size of the third grip 1043 in the first direction.

In this embodiment, because the first frame segments D1 are spaced from each other and correspond to the plurality of endpoints of an open area 101 close to the second sub-frame, the periphery of the open area 101 can be stretched by a force. In addition, when the second frame segment D2 is arranged between two adjacent first frame segments D1 and the fourth grip 1044 is arranged on the second frame segment D2, the fourth grip 1044 can be used to provide force stretching between the frame 200 and the metal mask for shielding in welding with the frame 200. Specifically, the fourth grip 1044 can be used to provide force stretching between two open areas 101, that is to say, a force for stretching is transmitted to the frame 200 through the fourth grip 1044 between corresponding open areas 101, so that a position on the frame 200 corresponding to the open areas 101 is stretched by a force to balance forces between the open areas 101, and further to avoid occurrence of wrinkles at the solid material area 102 between the open areas 101.

Comparing the fourth grip 1044 with the third grip 1043, the third grip 1043 is located at a side of the open area 101 close to the second sub-frame, which provides force stretching for the solid material area 102 between the open area 101 and the second sub-frame, has a smaller area of solid material, and requires a smaller stretching force, while the fourth grip 1044 corresponds to the solid material area 102 between the open areas 101, and generally, the solid material area 102 between the two open areas 101 is used to shield an area between two display areas 401, with a larger area and thus a larger required stretching force. Therefore, the third grip 1043 is set to be small in size while the fourth grip 1044 is set to be large in size, which can match the area of the corresponding solid material area 102, thus providing a matched stretching force and avoiding wrinkles caused by an over-sized or under-sized force.

The size of the third grip 1043 being smaller than the size of the fourth grip 1044 may involves that a size of the fourth grip 1044 in the second direction is larger than a size of the third grip 1043 in the second direction, that is, a width of the third grip 1043 is smaller than a width of the fourth grip 1044 when viewed from top of the base plate 100.

Alternatively, a size of the fourth grip 1044 in the first direction is larger than a size of the third grip 1043 in the first direction, that is, a length of the third grip 1043 is smaller than a length of the fourth grip 1044 when viewed from top of the base plate 100.

Alternatively, the width and length of the fourth grip 1044 are both greater than the width and length of the third grip 1043.

In practice, a size relationship between the third grip 1043 and the fourth grip 1044 can be set as any of the above, which will not be described in detail here again.

Certainly, in some other embodiments, as shown in FIG. 8, a fifth grip 104 can be provided at both end positions of the second sub-frame, that is, at corner positions of the second sub-frame close to the first sub-frame, and a size of the fifth grip 104 can be larger than the size of the fourth grip 1044. The fifth grip 104, similar to the first grip 1041, can be used to provide the metal mask for shielding with stretching forces at four endpoints for aligning the metal mask for shielding with the frame 200, thus ensuring stability between the metal mask for shielding and the frame 200.

In some examples, the grips 104 described above may have chamfers. Generally, the chamfers of the grips 104 arranged on the base plate 100 may be as large as possible. For example, axial diameters of the chamfers of the grips 104 may be greater than 5 mm and less than 10 mmm.

In this case, an axial diameter of a chamfer of the second grip 1042 located on the first sub-frame may be the same as an axial diameter of a chamfer of the grip 104 located on the second sub-frame. Alternatively, the axial diameter of the chamfer of the grip 104 located on the first sub-frame may be different from the axial diameter of the chamfer of the grip 104 located on the second sub-frame.

In a case where the axial diameter of the chamfer of the grip 104 located on the first sub-frame is different from the axial diameter of the chamfer of the grip 104 located on the second sub-frame, a size of the chamfer of the grip 104 on the first sub-frame may be larger or smaller than a size of the chamfer of the grip 104 on the second sub-frame.

In a case where the grip 104 has the chamfer, assembly between the metal mask for shielding and the frame 200 can be facilitated.

Certainly, the axial diameter of the chamfer of the grip 104 can also be set according to actual needs. For example, when an area of the solid material at a side of the open area 101 close to the grip 104 is small, the size of the chamfer of the grip 104 can be set to be small, such as 0.5 mm, and when the area of the solid material at the side of the open area 101 close to the grip 104 is large, there can be enough solid material to support and thus the size of the chamfer of the grip 104 can be set to be large, such as 10 mm, which is not specifically limited in the present disclosure.

In the following, an example is given to illustrate a metal mask for shielding of the present disclosure.

Referring to FIG. 8, FIG. 8 shows a top plan view of a metal mask for shielding provided for an octagonal irregular display area 401. As shown in FIG. 8, the metal mask for shielding includes:
a base plate 100. A plurality of open areas 101 are distributed in the lateral direction of the base plate 100, and the plurality of open areas 101 are arranged in a row in the lateral direction, and a shape of the open area 101 is consistent with a shape of the display areas 401, which is also of an irregular octagon shape, and the shape of the display area 401 can be defined by the open area 101. The open area 101 includes eight sides such as L1 to L8. Sides L1, L2 and L3, and L4, L5 and L6 are short sides of the open area 101, and L7 and L8 are long sides of the open area 101, L1 and L3 can be symmetrical with respect to L2, certainly, they can also be asymmetrical; and L4 and L6 can be symmetrical with respect to L5, and certainly, they can also be asymmetrical. L7 and L8 are two opposite sides.

The open areas 101 are equally spaced, and an area on the base plate 100 except the open areas 101 is the solid material area 102, and the solid material area 102 is used to provide shielding when the organic light-emitting material is evaporated.

The solid material area 102 includes a plurality of first through-etching areas 1032 and a plurality of second through-etching areas 1033. Sides of each open area 101 close to the sides L1, L3, L4 and L6 are respectively provided with a first through-etching area 1032, and sides of each open area 101 close to the sides L7 and L8 are respectively provided with a second through-etching area 1033.

Certainly, as shown in FIG. 8, the second through etching area 1033 is located between long sides of two open areas 101, and thus there is a second through-etching area 1033 between two adjacent open areas 101.

The first through-etching area 1032 includes a plurality of through holes 1031 spaced apart from each other, and the plurality of through holes 1031 includes square through holes 1031 and right-angled triangular through holes 1031, and the through holes 1031 of two shapes are arranged in a large triangle, so as to form a Dummy area in a short-side direction of the open area 101, which can balance force on the solid materials around the open area 101 during welding and net stretching and avoid wrinkles. It should be noted that in the first through-etching area 1032, a distance between a through hole 1031 closest to the open area 101 and the open area 101 needs to be greater than or equal to 5 mm and less than or equal to 10 mm.

The second through-etching area 1033 includes a through hole 1031 extending along the long side (L7) of the open area 101, that is, a strip-shaped through hole 1031, which is used to balance a force stressed by the solid material between adjacent open areas 101 during welding and net stretching and to avoid wrinkles of the solid material between adjacent open areas 101.

The first through-etching area 1032 has a first half-etching zone 1034, and the first half-etching zone 1034 surrounds a plurality of through holes 1031 in the first through-etching area 1032, and solid material at the first half-etching zone is half-etching, and a thickness of the solid material at the first half-etching zone 1034 is smaller than a thickness of another part of the base plate 100, so as to reduce an overall weight of the shielding metal plate.

The second through-etching area 1033 includes a half-etching zone around an edge of the through hole 1031, that is, solid material at the edge of the through hole 1031 in the second through-etching area 1033 is half etching and its thickness is half the thickness of the base plate 100, so as to reduce the overall weight of the shielding metal plate.

The solid material area 102 further includes a second half-etching zone 1011 surrounding the open area 101, and the second half-etching zone 1011 is half-etching, that is, solid material at an edge of the open area 101 is also half-etching, so as to reduce the overall weight of the shielding metal plate. Therefore, contact between this part and the FMM strip can be reduced, and rubbing of the FMM strip can be avoided

The base plate 100 includes two opposite first sub-frames and two opposite second sub-frames. A plurality of first grips 1041 are respectively arranged at both end positions of the first sub-frame, and a plurality of second grips 1042 are arranged at a frame segment between the both end positions. A size of the second grip 1042 is smaller than a size of the first grip 1041, and a spacing distance between second grips 1042 is larger than a spacing distance between first grips 1041 located at a same end. The first grip 1041 is used to ensure stability between the shielding metal plate and the frame 200, and the second grip 1042 is used to improve the alignment accuracy between the open area 101 and the FMM strip during welding and net stretching. The sizes of the chamfers of the first grip 1041 and the second grip 1942 can be increased as much as possible, for example, increased to 5 mm to 10 mm.

There are a plurality of first frame segments D1 spaced and second frame segments D2 located between the first frame segments D1 on each second sub-frame, an orthographic projection of the first frame segment D1 on the open area 101 can cover a plurality of endpoints of the open area 101 at its side close to the second sub-frame, and two ends of the first frame segment D1 are respectively provided with a third grip 1043 and the third grip 1043 is used for providing force stretching for each open area 101. A fourth grip 1044 is provided at a midpoint of the second frame segment D2, and the fourth grip 1044 is used for providing force stretching for the solid material area 102 between the open areas 101, so as to reduce wrinkles caused by weak stretching of the solid material area 102 here. The size of the third grip 1043 may be smaller than the size of the fourth grip 1044. The sizes of the chamfers of the third grip 1043 and the fourth grip 1044 can be increased as much as possible, for example, increased to 5 mm to 10 mm.

Based on a same inventive concept, a net stretching assembly can be further provided in the present disclosure. Referring to FIG. 12, FIG. 12 shows a top plan view of the net stretching assembly, which includes a frame 200 and the metal mask for shielding, and the metal mask for shielding is connected to the frame 200.

The metal mask for shielding can be welded to the frame 200.

Because the metal mask for shielding is provided with the plurality of through-etching areas 103 around the open area 101, and the through holes 1031 are provided in the through-etching area 103, and in this way, force transmission in welding can be balanced through the through holes 1031, and thus occurrence of wrinkles at the solid material area 102 of the metal mask for shielding can be avoided, and thus deformation of the open area 101 can be avoided, so that the FMM strips are relatively smoother in subsequent stretching, in which case the color mixing yield of the red/green/blue sub-pixels in the luminescent layer can be improved, thus facilitating improvement of the product yield of the display panel 400.

In an alternative example, the metal mask for shielding includes a plurality of grips 104 arranged at intervals on the first sub-frame and/or on the second sub-frame, and the frame 200 includes a plurality of connecting grooves corresponding to the plurality of grips 104 respectively. The plurality of grips 104 are respectively embedded in the plurality of connecting grooves.

In this embodiment, a plurality of grips 104 are arranged at intervals on the first sub-frame and/or the second sub-frame of the metal mask for shielding, a specific arrangement mode of the grips 104 can refer to description of above embodiments, in which a plurality of connecting grooves are arranged the frame 200 at positions corresponding to the plurality of grips 104, that is, at a side of the frame 200 close to the metal mask for shielding. Shapes of the connecting grooves can be adapted to shapes of the grips 104 so that the grips 104 can be welded to corresponding connecting grooves.

The grips 104 arranged on the first sub-frame and the second sub-frame can not only ensure stability between the frame 200 and the metal mask for shielding, but also ensure alignment accuracy between the open area 101 on the metal mask for shielding and the FMM strips. Therefore, after the metal mask for shielding is welded to the frame 200, with cooperation between the grips 104 and the connecting grooves, a flat and wrinkle-free net stretching assembly can be obtained.

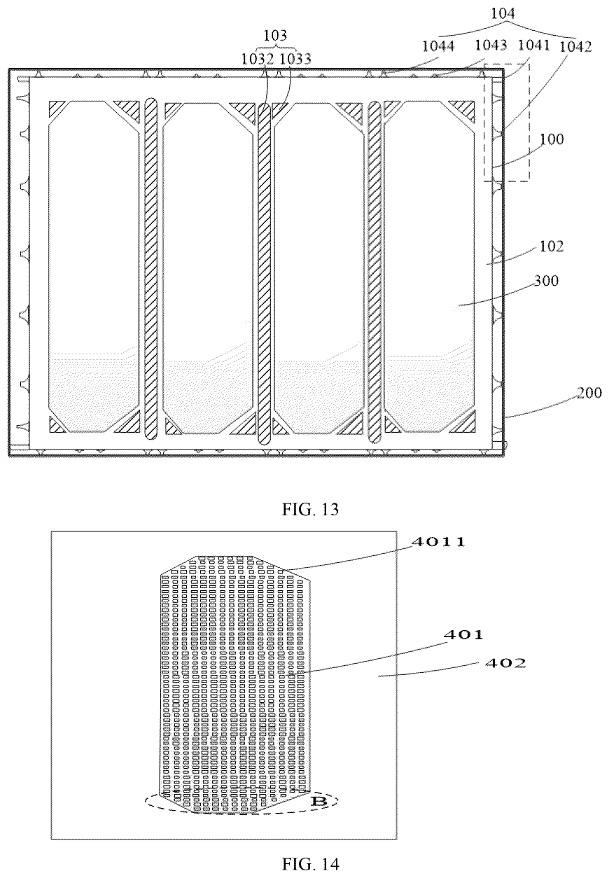

Based on a same inventive concept, a mask can be further provided in the present disclosure. Referring to FIG. 13, FIG. 13 shows a top plan view of the mask, which as shown in FIG. 13, includes the metal mask for shielding or the net stretching assembly.

The mask further includes a mask strip 300 (i.e. FMM strip), and the mask strip 300 is connected to the open area 101 of the metal mask for shielding, and the mask strip 300 is defined with a plurality of openings for defining a shape of a sub-pixel 4011 in a display area 401.

In this embodiment, after the net stretching assembly is obtained, the mask strip 300 can be connected to the open area 101 of the metal mask for shielding, and one mask strip 300 can be connected to a corresponding open area 101. The mask strip 300 can be connected to the open area 101 in a welding mode. The mask strip 300 is defined with a plurality of openings, and one opening is used to define one sub-pixel 4011.

Specifically, a plurality of openings defined on the FMM strip can be arranged in array, and the plurality of openings can be of any one of a circle shape, a triangle shape, a square shape or a rectangle shape.

With this mask and because the solid material area 102 around the open area 101 of the metal mask for shielding has the through-etching area 103, and the through-etching area 103 is defined with the through hole 1031, stretching forces can be balanced and wrinkles can be avoided, so that when the FMM strips are welded, welding can be made based on the flat opening area 101. In welding, the through hole 1031 of the through-etching area 103 can make an applied force be evenly transmitted in the metal mask for shielding, thus avoiding occurrence of wrinkles of the FMM strips, further improving flatness of the FMM strips, and thus improving the color mixing yield.

Moreover, the provided grips 104 can not only ensure stability between the frame 200 and the metal mask for shielding, but also ensure alignment accuracy between the open area 101 on the metal mask for shielding and the FMM strips. Therefore, when the FMM strips are welded to the open area 101, a force can be uniformly transmitted to the frame 200 through the grips 104, further avoiding the wrinkles of the FMM strips, and further improving the flatness of the FMM strips.

In a case where the metal mask for shielding has the first half-etching zone 1034 and the second half-etching zone 1011, a side of the metal mask for shielding close to the FMM strips can be a side with a half-etching, and the solid material area 102 has a depression because of half etching of the solid material area 102. In this case, a side of the metal mask for shielding with the depression is arranged close to the FMM strips, which can avoid rubbing of the solid material to the FMM strips when the FMM strips are welded.

In an embodiment, as described above, the FMM strips can be regular or irregular in shape. Specifically, the shapes of the mask strips 300 can be adapted to the opening shapes of the open areas 101, as shown in FIGS. 12 and 13, which show a case where the mask strips 300 are adapted to the open areas 101 in shape. The shapes of the mask strips 300 may not be adapted to the shapes of the open areas 101, and in case of being adapted, a shape formed by arranging a plurality of openings on a mask strip 300 is consistent with an opening shape of the open area 101. As shown in FIG. 13, it is shown a schematic view of the shape of the mask strip 300 being adapted to the opening shape of the open area 101.

When the mask strip 300 is irregular in shape, after the mask strip 300 covers the open area 101, a part of openings may be located outside the open area 101. As shown in FIGS. 3 to 5, if the mask strip 300 is a rectangular strip, a part of openings may be located in the through-etching area 103, and when the through holes 1031 of the through-etching area 103 overlaps with openings of the mask strip 300, the organic light-emitting material may be deposited on the display panel 400 through the through holes 1031, thus affecting the product yield.

Thus, in a case where the metal mask for shielding further includes a protective layer, an orthographic projection of the protective layer on the metal mask for shielding covers the through-etching area 103 at a side of the open area 101. An orthographic projection of the mask strip 300 on the metal mask for shielding also covers the protective layer.

Therefore, the protective layer can be arranged between the mask strip 300 and the through-etching area 103, which can prevent the organic light-emitting material from leaking from the through holes 1031 on the through-etching area 103 to the non-display region 402 of the display panel 400, and the mask strip 300 can be prepared in a regular shape, thus facilitating preparation of the mask strip 300, that is, a mask strip 300 with a conventional shape can also be suitable for preparation of a luminescent layer of the display area 401 with an irregular shape. It is not necessary to separately prepare an adaptive mask strip 300 for the display area 401 with the irregular shape, which reduces production cost.

Based on a same inventive concept, a display panel 400 is further provided in the present disclosure. Referring to FIG. 14, FIG. 14 shows a top plan view of the display panel 400. As shown in FIG. 14, the display panel 400 can include a substrate including a display area 401 and a non-display area 402; and
a pixel definition layer 403 including a plurality of pixel areas 4031 arranged in array; and
a luminescent layer located on a side of the pixel definition layer 403 away from the substrate, including a light-emitting pattern located in the display area 401, an orthographic projection of the light-emitting pattern on the substrate covering a part of the pixel areas 4031 in the pixel definition layer 403.

The luminescent layer is obtained by evaporating an organic light-emitting material based on the mask described above.

The substrate can be a glass substrate or a substrate made of other materials.

The non-display area 402 may surround the display area 401 and be adjacent to the display area 401. The luminescent layer includes the light-emitting pattern, and the orthographic projection of the light-emitting pattern on the substrate can cover the display area 401 without overlapping with the non-display area 402.

In this embodiment, the pixel definition layer 403 is arranged between the luminescent layer and the substrate, and the pixel definition layer 403 may include a plurality of pixel openings spaced apart from each other, and the orthographic projection of the pixel definition layer 403 on the substrate may cover the luminescent layer, or an orthographic projection of the luminescent layer on the substrate is located in the pixel definition layer 403.

One pixel opening is configured to define an area where one sub-pixel 4011 is located. When the organic light-emitting material is actually evaporated, the organic light-emitting material is evaporated into the pixel opening through the openings on the FMM strip, thus forming respective sub-pixels 4011.

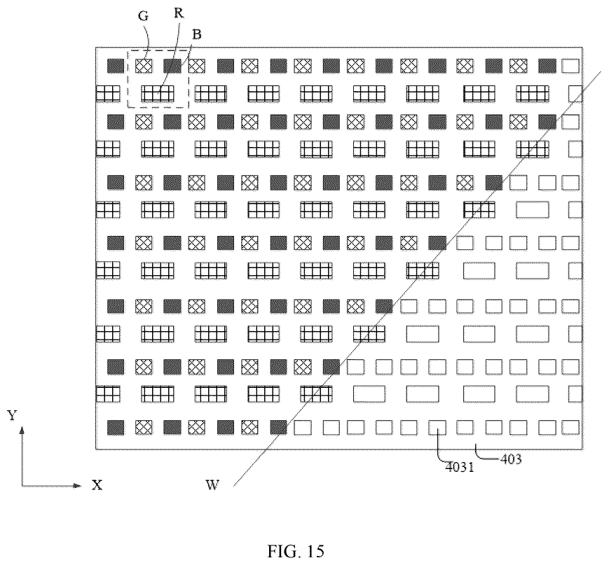

Since the open area 101 on the metal mask for shielding in the present disclosure defines the shape of the display area 401, a pixel opening in an area on the pixel definition layer 403 covered by the open area 101 is evaporated with the organic light-emitting material to form the sub-pixel 4011, while a pixel opening in an area not covered by the open area 101 is not evaporated with the organic light-emitting material to form a non-display area 402, then an orthographic projection of a finally formed light-emitting pattern on the substrate covers a part of a pixel areas 4031 in the pixel definition layer 403. Referring to FIG. 15, FIG. 15 shows a top plan view of the formed light-emitting pattern. As shown in FIG. 15, the pixel opening in the area covered by the open area 101 is evaporated with the organic light-emitting material to form the sub-pixel 4011, while the pixel opening in the area not covered by the open area 101 is not evaporated with the organic light-emitting material to form the non-display area 402. That is to say, although the pixel opening is defined, the sub-pixel 4011 is not formed here. Thus, in preparing the display area 401 with the irregular shape, it is only necessary to define the open area 101 on the metal mask for shielding, and it is not necessary to prepare a pixel definition layer 403 with an irregular shape for a display area 401 to be displayed, thus simplifying a manufacturing process of the display panel 400.

When the organic light-emitting material is evaporated using the mask to obtain the luminescent layer, an orthographic projection of the solid material area 102 of the metal mask for shielding on the substrate can be located in the non-display area 402, and an orthographic projection of the open area 101 of the metal mask for shielding on the substrate can be located in the display area 401.

The mask includes the metal mask for shielding and the mask strip 300 located in the open area 101 of the metal mask for shielding, and the organic light-emitting material is deposited on the substrate through the openings on the mask strip 300, to form a plurality of sub-pixels 4011.

Since the open area 101 can be irregular in shape, in one case, a side of the light-emitting pattern on the luminescent layer close to the non-display area 402 is formed with a side extending in at least one target direction, and the target direction is different from an extending direction of the frame of the display panel 400.

As shown in FIG. 15, FIG. 15 shows an enlarged schematic view of a dotted line box B in FIG. 14. Specifically, a schematic top view of the display panel 400 with the sub-pixel 4011 deposited is shown. As shown in FIG. 15, the frame of the display panel 400 includes a frame extending in an X direction and a frame extending in a Y direction, and the X direction is orthogonal to the Y direction. A side extending along at least one target direction W is formed at a part of the light-emitting pattern close to the non-display area 402, and the target direction W is different from an extending direction of the frame of the display panel 400. The target direction W may be a direction intersecting with the frame of the display panel 400, but in practice, it can be understood as a direction which is not parallel to two opposite frames of the display panel 400.

For example, as shown in FIGS. 15 and 12, the target direction of the side of the light-emitting pattern layer in FIG. 15 may be consistent with an extending direction of the side L6 of the open area on the metal mask for shielding in FIG. 12, that is, with definition of the shape of the open area, the organic light-emitting material is deposited on a part of the pixel areas on the pixel definition layer, so as to obtain the light-emitting pattern layer consistent with the open area in shape.

As shown in FIG. 15, the sub-pixel 4011 of the display panel 400 includes a sub-pixel R, a sub-pixel G and a sub-pixel B. The sub-pixel R, sub-pixel G and sub-pixel B forms one pixel, and the sub-pixel R, the sub-pixel G and the sub-pixel B can be arranged in a mode shown in a dashed box in FIG. 15. After the organic light-emitting material is deposited, a part of the pixel areas 4031 on the pixel definition layer 403 corresponding to the sub-pixel 4011 is deposited with the organic light-emitting material. It can be seen that the pixel areas deposited with the organic light-emitting material constitute a light-emitting pattern, and the sub-pixel 4011 is only deposited on the part of the pixel areas 4031 for the luminescent layer, so that the luminescent layer has a side extending in the target direction, as shown by a side in the direction W.

Because the display panel 400 adopts the metal mask for shielding described in above embodiments as a mask and the metal mask for shielding can serve to avoid wrinkles by providing the through-etching areas 103, an overall weight of the metal mask for shielding can be reduced by half-etching at an edge of the open area 101 and at the through-etching area 103, thus reducing sagging amount, so that when the organic light-emitting material is evaporated onto the base plate using the mask, the color mixing yield of the red/green/blue sub-pixels in the luminescent layer can be improved.

Following indexes of the display panel 400 manufactured by using the metal mask for shielding meet requirements:
CPA (continuous pinwheel alignment) &Cell Size: Within ±100 μm; (Spec: ±100 μm); Flatness: ≤250 um (Spec: ≤350 um).

Finally, it should be noted that unless otherwise defined, the terms “first”, “second”, and similar words used in this specification do not indicate any order, quantity, or importance, but are only used to distinguish between different components. Moreover, the terms “including”, “containing”, or any other variation thereof are intended to encompass non-exclusive inclusion, such that a process, method, good, or equipment that includes a series of elements includes not only those elements, but also other elements not explicitly listed, or elements inherent to such process, method, good, or equipment. Without further limitations, the element defined by the statement “including one,” does not exclude the existence of other identical elements in the process, method, product, or device that includes the element in question. Words like “connected” or “connection” are not limited to physical or mechanical connections, but can include electrical connections, whether direct or indirect.

The above provides a detailed introduction to a metal mask for shielding, net stretching assembly, mask, and display panel provided in the present disclosure. Specific examples are applied in this specification to explain the principles and implementation methods of the present disclosure. The above embodiments are only used to help understand the methods and core ideas of the present disclosure. Meanwhile, for persons skilled in the art, there may be changes in the specific implementation methods and application scope based on the ideas disclosed in this document. In summary, the content of this specification should not be understood as limiting the present disclosure.

After considering the specification and practicing the invention disclosed herein, persons skilled in the art will easily come up with other implementation schemes disclosed herein. The present disclosure is intended to cover any variations, uses, or adaptive changes of the present disclosure that follow the general principles of the present disclosure and include common knowledge or customary technical means in the art that are not disclosed in the present disclosure. The specification and embodiments are only considered exemplary, and the true scope and spirit of the present disclosure are indicated by the following claims.

It should be understood that the present disclosure is not limited to the precise structure described above and shown in the accompanying drawings, and various modifications and changes can be made without departing from its scope. The scope of the present disclosure is limited only by the appended claims.

The term “one embodiment”, “embodiment” or “one or more embodiments” referred to in this specification means that specific features, structures or characteristics described in conjunction with the embodiments are included in at least one embodiment disclosed herein. Furthermore, please note that the word “in one embodiment” may not necessarily refer to the same embodiment.

In the specification provided here, a large number of specific details are explained. However, it can be understood that the disclosed embodiments can be practiced without these specific details. In some examples, well-known methods, structures, and techniques are not shown in detail to avoid blurring the understanding of this specification.

In the claims, any reference symbols located between parentheses should not be constructed as limitations on the claims. The word “including” does not exclude the existence of elements or steps that are not listed in the claims. The word “a/an” or “one” before the component does not exclude the existence of multiple such components. The present disclosure can be implemented by means of hardware comprising several different components and by means of appropriately programmed computers. In the unit claims listing several devices, several of these devices may be specifically embodied through the same hardware item. The use of words such as first, second, and third does not indicate any order. These words can be interpreted as names.

Finally, it should be noted that the above embodiments are only used to illustrate the disclosed technical solution and not to limit it. Although the present disclosure has been described in detail with reference to the aforementioned embodiments, those skilled in the art should understand that they can still modify the technical solutions described in the aforementioned embodiments, or equivalently replace some of the technical features. And these modifications or substitutions do not depart from the essence and scope of the corresponding technical solutions disclosed in the present disclosure.

1. A metal mask for shielding, comprising a base plate, wherein the base plate comprises a plurality of open areas spaced apart from each other and a solid material area except the plurality of open areas; wherein
the plurality of open areas penetrate through the base plate, and the plurality of open areas are configured to define a shape of a display area; and
the solid material area comprises at least one through-etching area, and different through-etching areas are close to different sides of an open area, and at least one through hole is opened in the at least one through-etching area, and an opening size of the at least one through hole is smaller than an opening size of the open area in a plane parallel to the base plate.

2. The metal mask for shielding according to claim 1, wherein the at least one through-etching area comprises a first through-etching area, the first through-etching area comprises a plurality of through holes spaced apart from each other, and the plurality of through holes are arranged in array.

3. The metal mask for shielding according to claim 1, wherein the at least one through-etching area comprises a second through-etching area, and a through hole in the second through-etching area extends along an edge of a side of the open area close to the second through-etching area.

4. The metal mask for shielding according to claim 3, wherein in a case where the at least one through-etching area comprises a first through-etching area, the first through-etching area is arranged close to a first side of the open area, and the second through-etching area is arranged close to a second side of the open area;
wherein a size of the first side in a length direction is smaller than a size of the second side in the length direction.

5. The metal mask for shielding according to claim 1, further comprising a protective layer, wherein the protective layer is located at a side of the at least one through-etching area away from the base plate, and an orthographic projection of the protective layer on the base plate covers the at least one through-etching area without overlapping with the open area.

6. The metal mask for shielding according to claim 1, wherein an opening shape of the through hole comprises at least one of a square, a rectangle, a triangle and a circle.

7. The metal mask for shielding according to claim 1, wherein the solid material area further comprises a shielding area, the shielding area is arranged around the at least one through-etching area; and the at least one through-etching area comprises a third through-etching area, the third through-etching area further comprises a first half-etching zone enclosing the through hole, and a thickness of the first half-etching zone is smaller than a thickness of the shielding area.

8. The metal mask for shielding according to claim 1, wherein the base plate further comprises a first sub-frame extending in a first direction and a second sub-frame extending in a second direction; and the solid material area and the plurality of open areas are located in an area enclosed by the first sub-frame and the second sub-frame;
wherein a number of open areas arranged along the first direction is smaller than a number of open areas arranged along the second direction.

9. The metal mask for shielding according to claim 8, wherein a plurality of grips are arranged at intervals on the first sub-frame and/or the second sub-frame, and the plurality of grips extend towards a side away from the open area.

10. The metal mask for shielding according to claim 9, wherein the plurality of grips are arranged at intervals on the first sub-frame and the second sub-frame; wherein
a number of grips arranged on the first sub-frame is smaller than a number of grips arranged on the second sub-frame; and/or,
sizes of a part of the grips arranged on the first sub-frame extending along the first direction are larger than sizes of a part of the grips arranged on the second sub-frame extending along the second direction.

11. The metal mask for shielding according to claim 9, wherein sizes of first grips located at both end positions of the first sub-frame in the first direction are larger than sizes of second grips in the first direction, wherein the second grips are grips on the first sub-frame except the first grips.

12. The metal mask for shielding according to claim 11, wherein the metal mask for shielding comprises a plurality of second grips and a plurality of first grips arranged at a same end of the first sub-frame;
wherein an interval distance between the first grips at the same end is smaller than an interval distance between the second grips.

13. The metal mask for shielding according to claim 9, wherein the second sub-frame comprises a plurality of first frame segments spaced apart from each other, each of the plurality of first frame segments covering orthographic projections of a plurality of endpoints of the open area close to the first frame segment on the first frame segment; and
wherein at least one third grip is provided on the first frame segment.

14. The metal mask for shielding according to claim 13, wherein a second frame segment is arranged between two adjacent first frame segments, and at least one fourth grip is further provided on the second frame segment, and a size of the at least one fourth grip in the second direction is larger than a size of the at least one third grip in the second direction; and/or the size of the at least one fourth grip in the first direction is larger than the size of the at least one third grip in the first direction.

15. The metal mask for shielding according to claim 1, wherein the solid material area further comprises a shielding area, and the shielding area is arranged around the through-etching area; the through-etching area further comprises a second half-etching zone surrounding the open area, and a thickness of a solid material of the second half-etching zone is smaller than a thickness of the shielding area.

16. A net stretching assembly, comprising a frame and the metal mask for shielding according to claim 1, wherein the metal mask for shielding is connected to the frame.

17. The net stretching assembly according to claim 16, wherein the metal mask for shielding comprises a plurality of grips arranged at intervals on the first sub-frame and/or on the second sub-frame, and the frame comprises a plurality of connecting grooves corresponding to the plurality of grips respectively;
wherein the plurality of grips are respectively embedded in the plurality of connecting grooves.

18. A mask, comprising the metal mask for shielding according to claim 1;
wherein the mask further comprises a plurality of mask strips, the plurality of mask strips are respectively connected to the plurality of open areas of the metal mask for shielding, a plurality of openings are opened on each of the plurality of mask strips, and the plurality of openings corresponding to sub-pixels in the display area;
wherein an orthographic projection of the mask strip on the metal mask for shielding covers the open area, and the plurality of mask strips are spaced apart from each other.

19. The mask according to claim 18, wherein the metal mask for shielding further comprises a protective layer, an orthographic projection of the protective layer on the metal mask for shielding covers the through-etching area at a side of the open area without overlapping with the open area; and
wherein the orthographic projection of the mask strip on the metal mask for shielding further covers the protective layer.

20. A display panel, comprising:
a substrate comprising a display area and a non-display area; and
a pixel definition layer comprising a plurality of pixel areas arranged in array; and
a luminescent layer located on a side of the pixel definition layer away from the substrate, comprising a light-emitting pattern located in the display area, wherein an orthographic projection of the light-emitting pattern on the substrate covers a part of the pixel areas in the pixel definition layer;
wherein the luminescent layer is obtained by evaporating an organic light-emitting material based on the mask according to claim 18.

21. (canceled)
